(19) United States
(12) Patent Application Publication
(10) Pub. No.: US 2011/0115100 A1
(43) Pub. Date: May 19, 2011

(54) SEMICONDUCTOR DEVICE

(75) Inventors: Naohisa OKUMURA, Yokohama-Shi (JP); Taku NISHIYAMA, Yokohama-Shi (JP)

(73) Assignee: KABUSHIKI KAISHA TOSHIBA, Tokyo (JP)

(21) Appl. No.: 12/948,160

(22) Filed: Nov. 17, 2010

(30) Foreign Application Priority Data
Nov. 18, 2009 (JP) 2009-263276
Nov. 10, 2010 (JP) 2010-251942

(51) Int. Cl. H01L 23/488

(52) U.S. Cl. 257/782; 257/E23.023

(57) ABSTRACT

According to one embodiment, a semiconductor device includes a base, a memory chip, a controller chip, and a plurality of passive components. The base includes a bonding pad. The memory chip is provided above the base and connected to the bonding pad by a wire. Data can be electrically stored in the memory chip. The controller chip is provided in a memory area including the memory chip in a direction from the memory chip toward the base and controls an operation of the memory chip. The passive components are provided in the memory area.

### CROSS REFERENCE TO RELATED APPLICATIONS

This application is based upon and claims the benefit of priority from the prior Japanese Patent Applications No. 2009-263276, filed on Nov. 18, 2009, and No. 2010-251942, filed on Nov. 10, 2010, the entire contents of which are incorporated herein by reference.

### FIELD

The present invention relates to a semiconductor device.

### BACKGROUND

Recently there is developed an SSD (Solid State Drive) in which a large-capacity storage device such as an HDD (Hard Disc Drive) is replaced with a flash memory.

The conventional SSD is a module in which plural semiconductor packages are mounted on a mounting board such as a motherboard that is a small-size rectangular board, and the conventional SSD is called a motherboard type SSD. Each semiconductor package is a BGA (Ball Grid Array) type semiconductor package in which a semiconductor chip is sealed by resin. The semiconductor package includes a memory package in which a NAND type flash memory serving as a nonvolatile semiconductor storage device is incorporated, a controller package in which a drive control circuit serving as a memory controller is incorporated, and passive components that include a capacitative component and a resistive component. A connector is provided in one short side in an outer peripheral edge portion of the mounting board.

However, because the motherboard type SSD has a large area, the motherboard type SSD cannot be mounted on compact instruments such as a mobile telephone.

### BRIEF DESCRIPTION OF THE DRAWINGS

FIG. 1A is a plan view of the semiconductor device according to the first embodiment.

FIG. 1B is a sectional view taken on a line A-A of FIG. 1A.

FIG. 2 is an enlarged view of an area B of FIG. 1B.

FIG. 3 is a schematic view illustrating a structure of a semiconductor device according to an embodiment of the present invention.

FIG. 4 is an enlarged view illustrating a periphery of the controller chip 12 of FIG. 1A.

FIG. 5A is a plan view of the semiconductor device according to the second embodiment.

FIG. 5B is a sectional view taken on a line A-A of FIG. 5A.

FIG. 6 is an enlarged view illustrating the periphery of the controller chip 12 of FIG. 5A.

FIG. 7A is a plan view of the semiconductor device according to the third embodiment.

FIG. 7B is a sectional view taken on a line A-A of FIG. 7A.

FIG. 8A is a plan view of the semiconductor device according to the fourth embodiment.

FIG. 8B is a sectional view taken on a line A-A of FIG. 8A.

FIG. 9 is an enlarged view of an area C of FIG. 8B.

FIG. 10A is a plan view of the semiconductor device according to the fifth embodiment.

FIG. 10B is a sectional view taken on a line A-A of FIG. 10A.

FIG. 11A is a plan view of the semiconductor device according to a combination of the second embodiment and the third embodiment.

FIG. 11B is a sectional view taken on a line A-A of FIG. 11A.

FIG. 12 is a sectional view for explaining a memory area MA including an alignment margin of a bonding pad.

### DETAILED DESCRIPTION

Embodiments will now be explained with reference to the accompanying drawings.

According to one embodiment, a semiconductor device includes a base, a memory chip, a controller chip, and a plurality of passive components. The base includes a bonding pad. The memory chip is provided above the base and connected to the bonding pad by a wire. Data can be electrically stored in the memory chip. The controller chip is provided in a memory area including the memory chip in a direction from the memory chip toward the base and controls an operation of the memory chip. The passive components are provided in the memory area.

Hereafter, a semiconductor device according to the present invention will be explained more specifically with reference to the drawings.

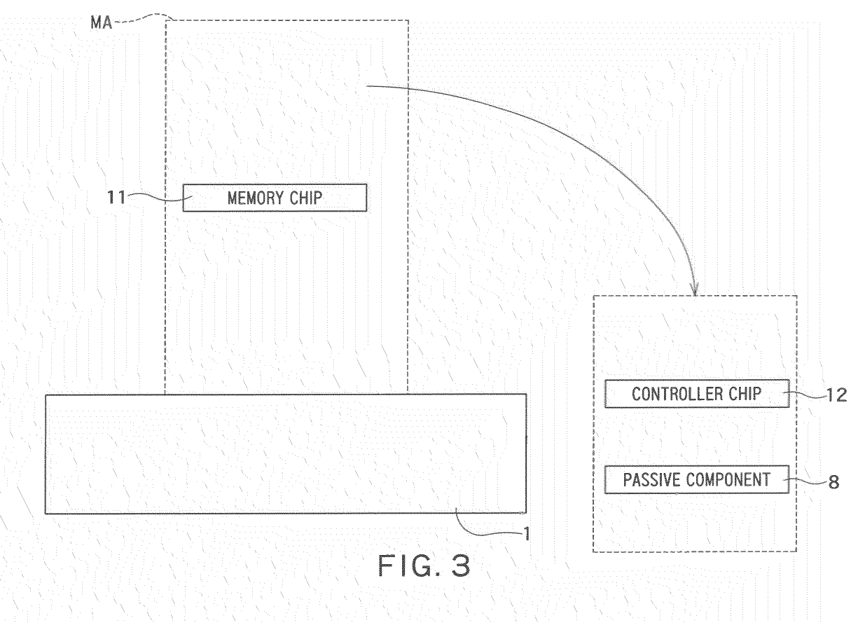

FIG. 3 is a schematic view illustrating a structure of a semiconductor device according to an embodiment of the present invention.

The semiconductor device of FIG. 3 includes a package substrate (base) 1, a memory chip 11, a controller chip 12, and plural passive components 8. The package substrate 1 includes one or more bonding pads. The memory chip 11 is a first semiconductor chip that is provided above the package substrate 1 and connected to the bonding pad by a wire. Data can electrically be stored in the memory chip 11. The controller chip 12 is a second semiconductor chip that controls an operation (for example, a read operation and a write operation) of the memory chip 11. At least part of the controller chip 12 is provided in an area (hereinafter referred to as “memory area”) MA where a plurality of memory chips 11 is provided in a direction from the memory chips 11 toward the package substrate 1. At least one passive component 8 is provided in the memory area MA. The passive component 8 is a chip capacitor or a chip resistive component. A chip capacitor or a chip resistive component used as the passive component 8 enable a height of the whole semiconductor device to be reduced.

In the semiconductor device according to the embodiment, at least part of the controller chip 12 and at least one passive component 8 are provided in the memory area MA. In other words, the passive component 8, the memory chip 11, and the controller chip 12 are provided in one package. The passive component 8, the memory chip 11, and the controller chip 12 are provided in the memory area MA when the semiconductor device is viewed from above. At this point, the memory area MA is an area that is sandwiched in between bonding pads located at both ends of the plural bonding pads on the package substrate 1, which are connected to the memory chip 11 through the wires, and includes the memory chip 11 when the semiconductor device is viewed from above. When only one bonding pad is provided, the memory area MA is an area that is sandwiched in between the bonding pad and an end portion of the semiconductor device and includes the memory chip 11. That is, an end portion of the memory area MA is defined by a position of the bonding pad on the package substrate 1.

### First Embodiment

A semiconductor device according to a first embodiment will be explained. In the semiconductor device according to the first embodiment, a passive component is provided in a package substrate, a memory chip is provided above the package substrate, and a controller chip is provided above the memory chip.

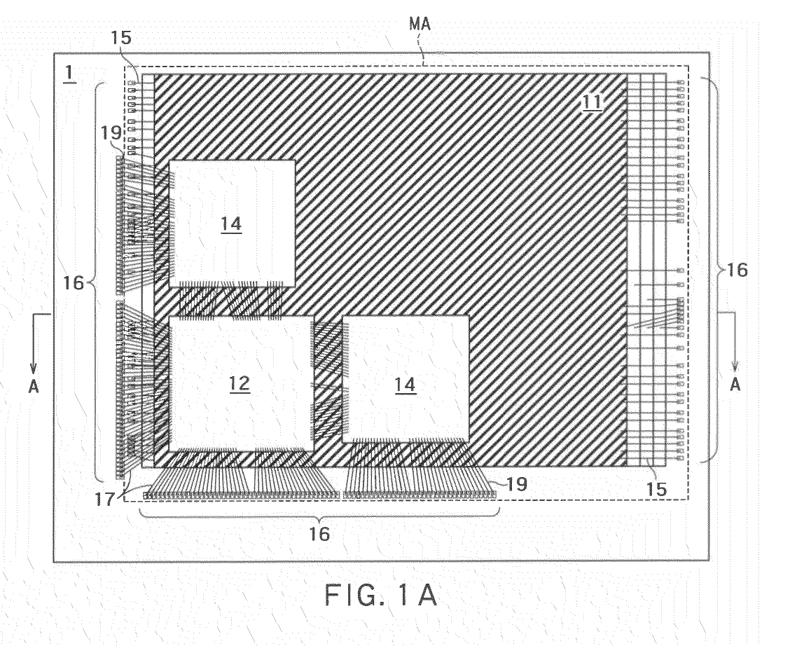

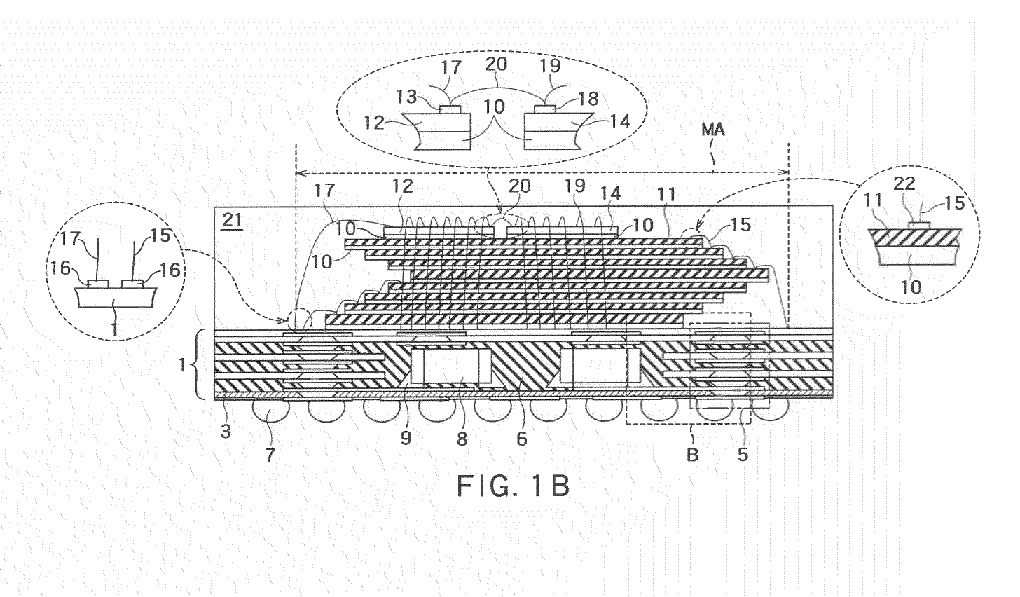

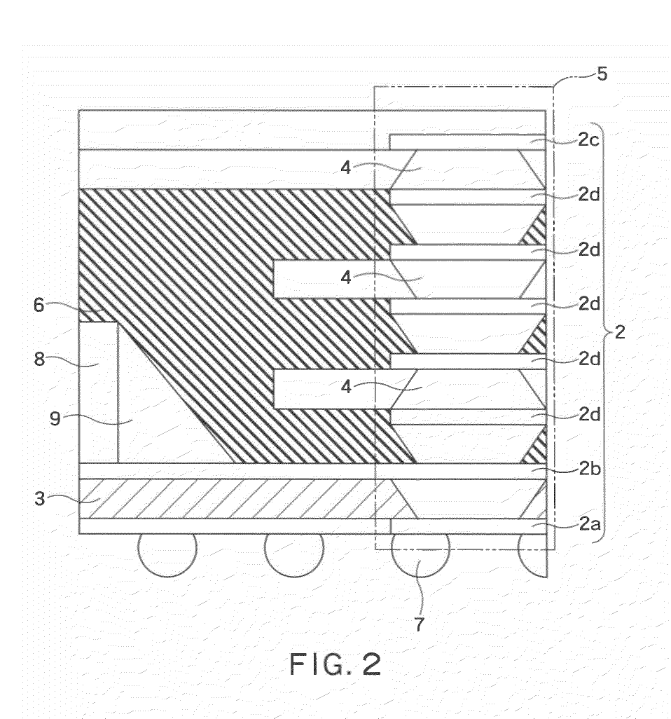

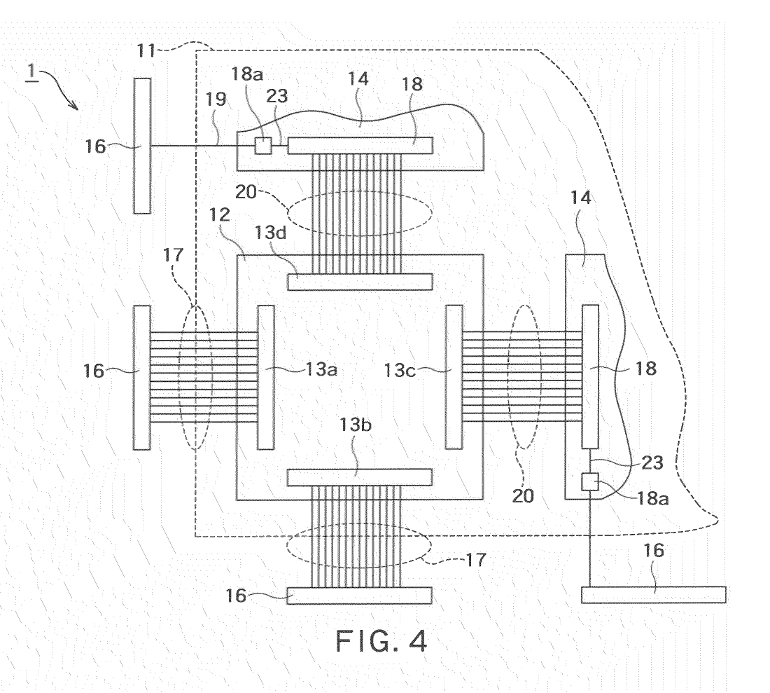

A configuration of the semiconductor device according to the first embodiment will be explained below. FIG. 1A is a plan view of the semiconductor device according to the first embodiment. FIG. 1B is a sectional view taken on a line A-A of FIG. 1A. FIG. 2 is an enlarged view of an area B of FIG. 1B. FIG. 4 is an enlarged view illustrating a periphery of the controller chip 12 of FIG. 1A.

As illustrated in FIG. 1B, the package substrate 1 includes a glass epoxy board 3, an electrode material 5, and the passive component 8. For example, the glass epoxy board 3 includes a glass board and a glass epoxy material in which an epoxy resin is cured on the glass board or a sheet-like bonding member (hereinafter referred to as “pre-preg”) in which the epoxy resin is semi-cured.

As illustrated in FIG. 2, the electrode material 5 includes plural interconnection layers 2. For example, each interconnection layer 2 is a copper interconnection. An external terminal 7 is connected to a lower surface of a lowermost layer (hereinafter referred to as “first interconnection layer”) 2a of the plural interconnection layers 2. For example, the external terminal 7 is a solder ball. A connection portion between the external terminal 7 and the first interconnection layer 2a is covered with a solder resist (not illustrated). In the first embodiment, the external terminal 7 may be directly connected to the first interconnection layer 2a through plating (Ni/Au or Ni/Pd/Au). As illustrated in FIG. 2, the first interconnection layer 2a is provided on the lower surface of the glass epoxy board 3, and a second interconnection layer 2b is provided on an upper surface of the glass epoxy board 3. Part of the second interconnection layer 2b is connected to the first interconnection layer 2a through a bump 4 formed on the glass epoxy board 3. The second interconnection layer 2b may be connected to the first interconnection layer 2a through a through-hole (not illustrated) formed in the glass epoxy board 3 instead of the bump 4. The second interconnection layer 2b is connected to the passive component 8 by a conductive material 9. For example, the conductive material 9 is solder.

As illustrated in FIGS. 1A and 1B, plural bonding pads 16 are provided on the package substrate 1. The bonding pads 16 are electrically connected to an uppermost layer (hereinafter referred to as “third interconnection layer”) 2c of the plural interconnection layers 2 of FIG. 2.

As illustrated in FIGS. 1B and 2, the passive component 8 and the conductive material 9 are covered with an insulating film layer 6. For example, the insulating film layer 6 is formed by melting the pre-preg. The electrode material 5 of FIG. 2 is provided so as to be adjacent to the passive component 8 with the insulating film layer 6 interposed therebetween. The electrode material 5 includes the plural interconnection layers 2 (the first interconnection layer 2a, the second interconnection layer 2b, the third interconnection layer 2c, and plural interconnection layers (hereinafter referred to as “fourth interconnection layer”) 2d between the second interconnection layer 2b and the third interconnection layer 2c), and the plural bumps 4. Each bump 4 is provided between the first interconnection layer 2a and the second interconnection layer 2b, between the second interconnection layer 2b and the fourth interconnection layer 2d of the lowermost layer, between the fourth interconnection layers 2d, and between the fourth interconnection layer 2d of the uppermost layer and the third interconnection layer 2c. The plural fourth interconnection layers 2d are provided between the second interconnection layer 2b and the third interconnection layer 2c, and are connected by the bumps 4. For example, the bumps 4 and the fourth interconnection layers 2d are alternately overlapped and the pre-preg is melted to bond the bump 4 and the fourth interconnection layer 2d by thermo-compression bonding, thereby forming the electrode material 5. Specifically, the pre-preg is melted to connect the bump 4 into contact with a conductive layer of the fourth interconnection layer 2d provided on the upper surface side of the bump 4, thereby connecting the fourth interconnection layers 2d to each other. The lower surface of the fourth interconnection layer 2d of the lowermost layer and the upper surface of the second interconnection layer 2b are connected by the bump 4. The lower surface of the third interconnection layer 2c and the upper surface of the fourth interconnection layer 2d of the uppermost layer are connected by the bump 4. As a result, the third interconnection layer 2c and the second interconnection layer 2b are connected with the plural fourth interconnection layers 2d interposed therebetween.

As illustrated in FIG. 1B, plural memory chips 11 are stacked on the package substrate 1 while a bonding member 10 is interposed between the memory chips 11. Each of the memory chips 11 includes plural first pads (memory pads) 22 on the upper surface thereof. In the first embodiment, plural pairs of the bonding members 10 and the memory chips 11 are formed. The pairs of the bonding members 10 and the memory chips 11 are alternately stacked such that center lines of the pairs are not overlapped. That is, the pairs of the bonding members 10 and the memory chips 11 are stacked such that the upper surface of the first pad 22 on the memory chip 11 of the lower layer is not overlapped on the pair of the bonding member 10 and the memory chip 11 of the upper layer.

As illustrated in FIG. 1B, a controller chip 12 is provided above the memory chip 11 of the uppermost layer with the bonding member 10 interposed therebetween. The controller chip 12 includes plural second pads (controller pads) 13 on the upper surface thereof. As illustrated in FIG. 1A, when the controller chip 12 and the memory chip 11 are viewed from above, an area of the controller chip 12 is smaller than that of the memory chip 11.

As illustrated in FIG. 1B, each first pad 22 on the memory chip 11 is connected to each bonding pad 16 on the package substrate 1 by a first wire 15. Each second pad 13 on the controller chip 12 is connected to each bonding pad 16 on the package substrate 1 by a second wire 17.

As illustrated in FIG. 1B, a relay member (third semiconductor chip) 14 is provided above the memory chips 11 of the uppermost layer with the bonding member 10 interposed therebetween. The relay member 14 is a semiconductor chip that relays the interconnection to connect the controller chip 12 and the package substrate 1. The relay member 14 includes plural third pads (relay pads) 18 on the upper surface thereof. As illustrated in FIG. 4, for example, the controller chip 12 has a square shape when viewed from above. Second pad groups (controller pad groups) 13a to 13d including the plural second pads 13 are provided in four sides of the controller chip 12. The controller chip 12 is provided near a corner of the memory chip 11. Accordingly, if the relay member 14 is not provided on the memory chip 11, a distance between the bonding pad 16 and each of the second pad groups 13c and 13d on the two sides of the controller chip 12 provided near one corner of the memory chip 11 is lengthened although a distance between the bonding pad 16 and each of the second pad groups 13a and 13b is shortened. On the other hand, when the relay member 14 is provided on the memory chip 11, a wire length between the bonding pad 16 and each of the second pad groups 13c and 13d can be shortened. Specifically, a third pad 18 on the relay member 14 and the second pad groups 13c and 13d on the controller chip 12 are connected by a third wire 20, the third pad 18 on the relay member 14 and a relay-chip third pad 18a are connected by a relay interconnection 23, and the relay-chip third pad 18a on the relay member 14 and the bonding pad 16 on the package substrate 1 are connected by a fourth wire 19. Therefore, the wire length can be shortened. For example, the first wire 15 to the fourth wire 19 are made of a gold wire, a silver wire, a copper wire, or a mixture thereof.

As illustrated in FIG. 1B, the plural memory chips 11, the controller chip 12, and the relay member 14 are covered with a resin 21.

In the first embodiment, the electrode material 5 is formed by the plural interconnection layers 2 and the bump 4. However, a scope of the present invention is not limited to the first embodiment. Alternatively, for example, a through-hole is formed in the package substrate, and the conductive material may be buried in the through-hole to form the electrode material 5.

According to the first embodiment, the memory chip 11 is provided above the package substrate 1, and the controller chip 12 and the relay member (relay chip) 14 are provided above the memory chip 11. The controller chip 12 is connected to the package substrate 1 by the wire bonding connection with the relay member (relay chip) 14 interposed therebetween. Therefore, the wire length between the package substrate 1 and the controller chip 12 can be shortened and the semiconductor device can be shrunk. Accordingly, the semiconductor device such as the SSD that can be mounted on a small-size instrument such as a mobile telephone is provided, which allows the semiconductor device to be operated at high speed.

When the semiconductor device is viewed from above, the memory chip 11 has the largest area among the areas of the memory chip 11, controller chip 12, passive component 8, and relay member 14. That is, when the semiconductor device is viewed from above, the controller chip 12, the passive component 8, and the relay member 14 are disposed so as to be included in the memory chip 11. As a result, the area can be reduced when the semiconductor device is viewed from above.

According to the first embodiment, the passive component 8 is directly provided in the package substrate 1. Accordingly, the passive component 8 can easily be mounted using solder and the like, and damage to the memory chip 11 and the like can be avoided during the mounting.

Additionally, the passive component 8 can be located near the external terminal 7. Accordingly, a noise included in a signal which is inputted from outside of the semiconductor device via the external terminal 7 can be effectively removed. It is particularly effective for the SSD which is operated at high speed.

### Second Embodiment

A semiconductor device according to a second embodiment will be explained. In the semiconductor device according to the second embodiment, a memory chip is provided on a package substrate, and a controller chip and passive components are provided above the memory chip. The description similar to that of the first embodiment will not be repeated.

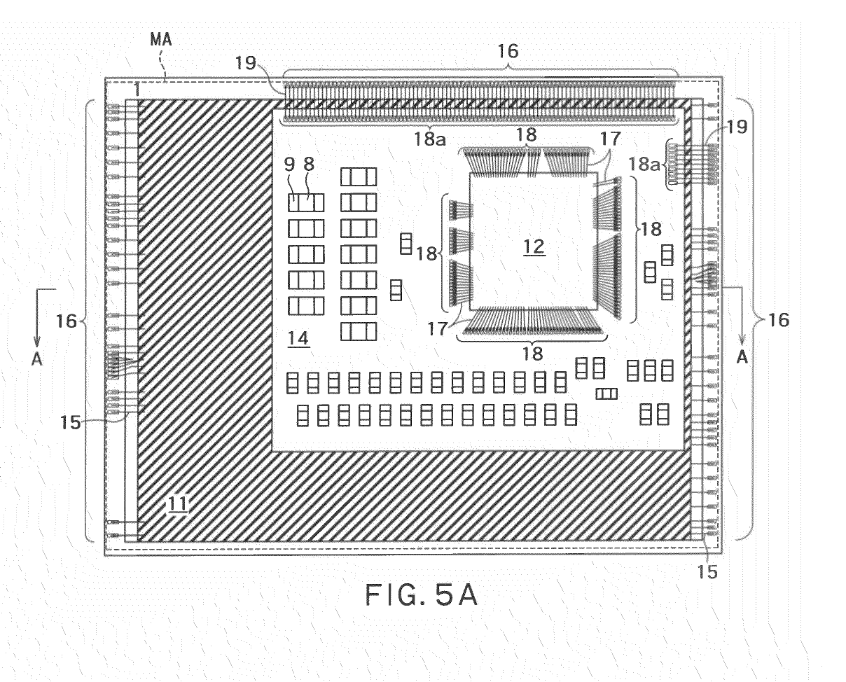

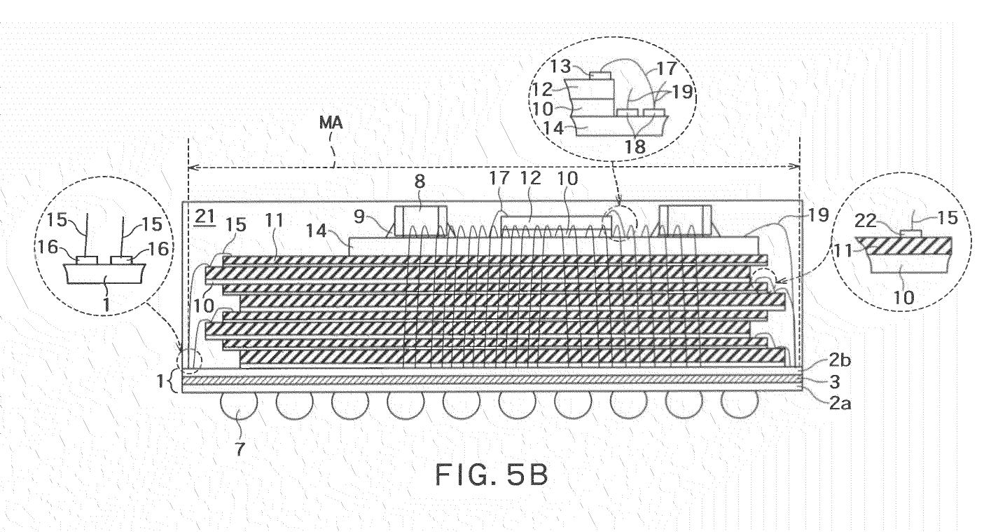

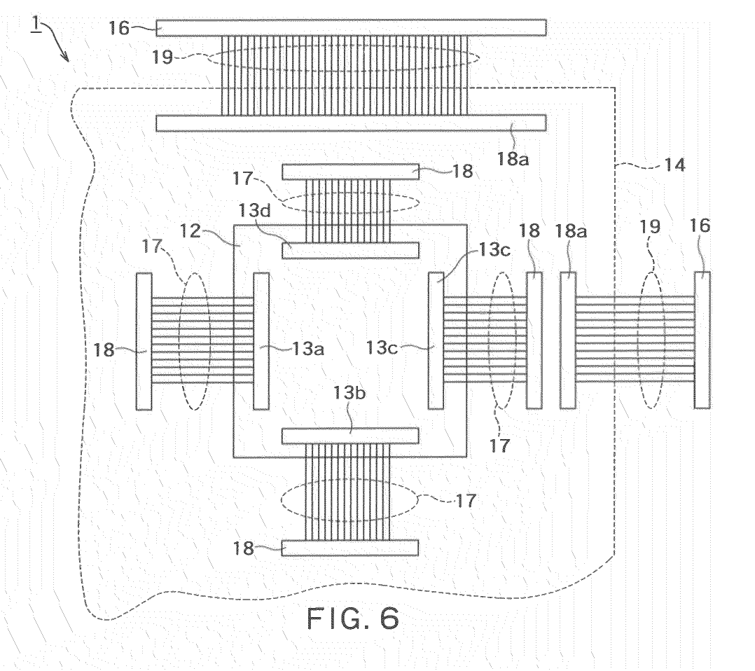

A configuration of the semiconductor device according to the second embodiment will be explained below. FIG. 5A is a plan view of the semiconductor device according to the second embodiment. FIG. 5B is a sectional view taken on a line A-A of FIG. 5A. FIG. 6 is an enlarged view illustrating the periphery of the controller chip 12 of FIG. 5A.

As illustrated in FIG. 5B, the package substrate 1 includes the first interconnection layer 2a, the glass epoxy board 3, and the second interconnection layer 2b. The glass epoxy board 3 is sandwiched in between the first interconnection layer 2a and the second interconnection layer 2b. For example, the glass epoxy board 3 includes the glass board and the glass epoxy material in which an epoxy resin is cured on the glass board or the sheet-like pre-preg in which the epoxy resin is semi-cured.

As illustrated in FIGS. 5A and 5B, the plural bonding pads 16 are provided on the package substrate 1. The bonding pads 16 are electrically connected to the uppermost layer (third interconnection layer) of the plural interconnection layers.

As illustrated in FIG. 5B, the plural memory chips 11 are stacked on the package substrate 1 while the bonding member 10 is interposed between the memory chips 11. The memory chip 11 includes the plural first pads (memory pads) 22 on the upper surface thereof. In the second embodiment, the plural pairs of the bonding members 10 and the memory chips 11 are provided. The pairs of the bonding members 10 and the memory chips 11 are alternately stacked such that the center lines of the pairs are not overlapped. That is, the pairs of the bonding members 10 and the memory chips 11 are stacked such that the upper surface of the first pad 22 on the memory chip 11 of the lower layer is not overlapped on the pair of the bonding member 10 and the memory chip 11 of the upper layer.

As illustrated in FIG. 5B, the relay member (relay substrate) 14 is provided above the memory chip 11 of the uppermost layer. The controller chip 12 is provided on the relay member 14 with the bonding member 10 interposed therebetween, and the passive components 8 are connected to the relay member 14 by the conductive material 9. The relay member 14 relays the interconnection to connect the controller chip 12 and the passive components 8 with the package substrate 1. The plural second pads (controller pads) 13 are provided on the controller chip 12. As illustrated in FIG. 5A, when the controller chip 12 and the memory chip 11 are viewed from above, the area of the controller chip 12 is smaller than that of the memory chip 11. The plural third pads (relay pads) 18 are provided on the relay member 14.

As illustrated in FIG. 5B, each first pad 22 on the memory chip 11 is connected to each bonding pad 16 on the package substrate 1 by the first wire 15. Each second pad 13 on the controller chip 12 is connected to each bonding pad 16 on the package substrate 1 by the second wire 17. Each third pad 18 on the relay member 14 is connected to each bonding pad 16 on the package substrate 1 by the fourth wire 19.

As illustrated in FIG. 6, for example, the controller chip 12 has a square shape when viewed from above, and the controller chip 12 includes the second pad 13 in four sides. The second pad groups (controller pad groups) 13a to 13d, in which the plural second pad 13 are included, are located on the four sides of the controller chip 12, respectively. The controller chip 12 is provided near one corner of the relay member 14. Accordingly, if the relay member 14 is not provided on the memory chip 11, the distance between the bonding pad 16 and each of the second pad groups 13a to 13d of the controller chip 12 is lengthened. On the other hand, the wire length between the bonding pad 16 and each of the second pad groups 13a to 13d can be shortened when the relay member 14 is provided on the memory chip 11. Specifically, the third pad 18 on the relay member 14 and the second pad groups 13a to 13d on the controller chip 12 are connected by the second wire 17, the third pad 18 on the relay member 14 and the relay-chip third pad 18a are connected by an internal interconnection (not illustrated), and the relay-chip third pad 18a on the relay member 14 and the bonding pad 16 on the package substrate 1 are connected by the fourth wire 19. Therefore, the wire length can be shortened. For example, the first wire 15 to the fourth wire 19 are made of a gold wire, a silver wire, a copper wire, or a mixture thereof.

As illustrated in FIG. 5B, the plural memory chips 11, the controller chip 12, and the relay member 14 are covered with the resin 21.

According to the second embodiment, the memory chip 11 is provided above the package substrate 1, the relay member (relay substrate) 14 is provided above the memory chip 11, and the controller chip 12 and the passive components 8 are provided above the relay member (relay substrate) 14. The controller chip 12 is connected to the package substrate 1 by the wire bonding connection with the relay member (relay substrate) 14 interposed therebetween. Therefore, the wire length between the package substrate 1 and the controller chip 12 can be shortened and the semiconductor device can be shrunk. As a result, the semiconductor device can be operated at high speed.

When the semiconductor device is viewed from above, the memory chip 11 has the largest area among the areas of the memory chip 11, controller chip 12, passive components 8, and relay member 14. That is, when the semiconductor device is viewed from above, the controller chip 12, the passive components 8, and the relay member 14 are disposed so as to be included in the memory chip 11. As a result, the semiconductor device can be shrunk when the semiconductor device is viewed from above.

According to the second embodiment, the relay substrate is used as the relay member 14 instead of the relay chip. As a result, the distance between the controller chip 12 and the passive elements 8 can be shortened. Accordingly, a noise included in a signal which is inputted to and outputted from the controller chip 12 can be effectively removed. Additionally, the controller chip 12 and the passive components 8 are provided above the relay substrate. Therefore, a layout for interconnects which have the same length as a length of each other can be easily designed. It is particularly effective for the SSD which is operated at high speed.

### Third Embodiment

A semiconductor device according to a third embodiment will be explained. In the semiconductor device according to the third embodiment, passive components are provided in a package substrate, a memory chip is provided above the package substrate, and a controller chip is provided between the package substrate and the memory chip.

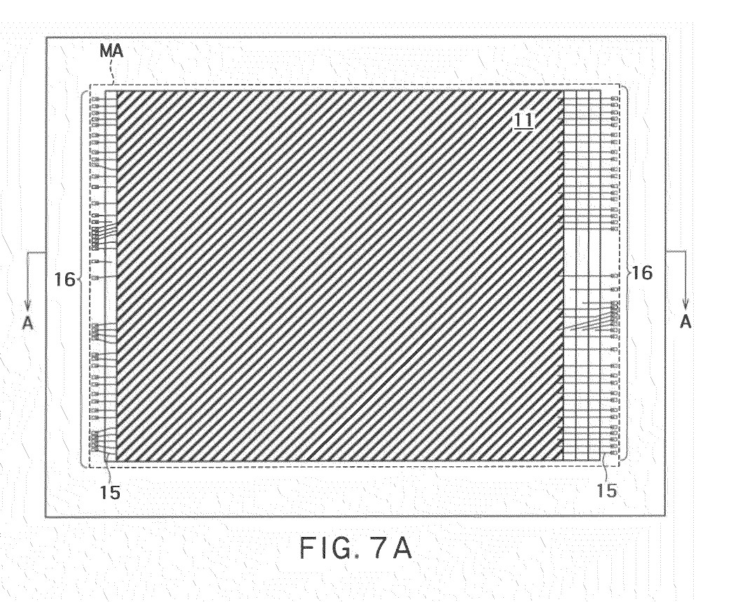

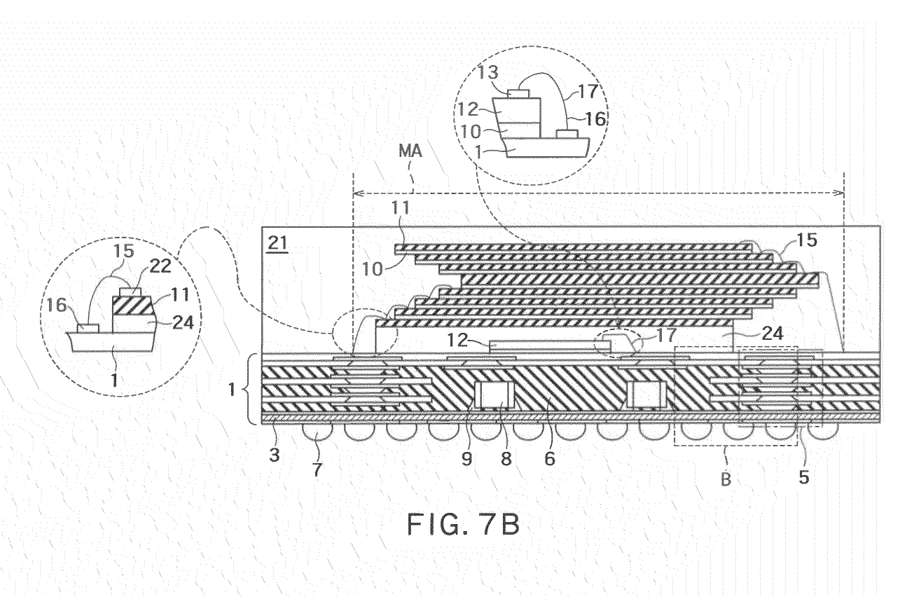

A configuration of the semiconductor device according to the third embodiment will be explained below. FIG. 7A is a plan view of the semiconductor device according to the third embodiment. FIG. 7B is a sectional view taken on a line A-A of FIG. 7A.

As illustrated in FIG. 7B, the package substrate 1 includes the glass epoxy board 3, the electrode material 5, and the passive components 8. For example, the glass epoxy board 3 includes the glass board and the glass epoxy material in which an epoxy resin is cured on the glass board or the sheet-like pre-preg in which the epoxy resin is semi-cured. The electrode material 5 is similar to that of the first embodiment (see FIG. 2).

As illustrated in FIGS. 7A and 7B, the plural bonding pads 16 are provided on the package substrate 1. The bonding pads 16 are connected to the uppermost layer (third interconnection layer) 2c of the plural interconnection layers 2 of FIG. 2.

As illustrated in FIG. 7B, the controller chip 12 is formed on the package substrate 1 with the bonding member 10 interposed therebetween. The controller chip 12 is sealed by a sealing member 24. The plural memory chips 11 are stacked on the sealing member 24 with the bonding member 10 interposed therebetween. The memory chip 11 includes the plural first pads (memory pads) 22 on the upper surface thereof. In the third embodiment, the plural pairs of the bonding members 10 and the memory chips 11 are provided. The pairs of the bonding members 10 and the memory chips 11 are alternately stacked such that the center lines of the pairs are not overlapped. That is, the pairs of the bonding members 10 and the memory chips 11 are stacked such that the upper surface of the first pad 22 on the memory chip 11 of the lower layer is not overlapped on the pair of the bonding member 10 and the memory chip 11 of the upper layer. However, the memory chip 11 of the lowermost layer is directly provided on the sealing member 24 without interposing the bonding member 10 therebetween.

As illustrated in FIG. 7B, the plural second pads (controller pads) 13 are provided on the controller chip 12. As illustrated in FIG. 7A, when the controller chip 12 and the memory chip 11 are viewed from above, the area of the controller chip 12 is smaller than that of the memory chip 11.

As illustrated in FIG. 7B, each first pad 22 on the memory chip 11 is connected to the bonding pad 16 on the package substrate 1 by the first wire 15. Each second pad 13 on the controller chip 12 is connected to the bonding pad 16 on the package substrate 1 by the second wire 17. For example, the first wire 15 and the second wire 17 are made of a gold wire, a silver wire, a copper wire, or a mixture thereof.

In the third embodiment, the electrode material 5 is formed by the plural interconnection layers 2 and the plural bumps 4. However, the scope of the present invention is not limited to the third embodiment. Alternatively, for example, the through-hole is formed in the package substrate 1, and the conductive material may be buried in the through-hole to form the electrode material 5.

According to the third embodiment, the memory chip 11 is provided above the package substrate 1, the controller chip 12 is provided between the package substrate 1 and the memory chip 11, and the passive components 8 are provided in the package substrate 1. The controller chip 12 is connected to the package substrate 1 by the wire bonding connection. Therefore, the wire length between the package substrate 1 and the controller chip 12 can be shortened and the semiconductor device can be shrunk. As a result, the semiconductor device can be operated at high speed. Additionally, because the relay member 14 is not required, the production cost of the semiconductor device can be reduced.

At this point, when the semiconductor device is viewed from above, the memory chip 11 has the largest area among the areas of the memory chip 11 and controller chip 12. That is, when the semiconductor device is viewed from above, the controller chip 12 and the passive components 8 are disposed so as to be included in the memory chip 11. As a result, the semiconductor device can be shrunk when the semiconductor device is viewed from above.

Additionally, according to the third embodiment, the passive components 8 are provided in the package substrate 1. Accordingly, the passive components 8 can easily be mounted using the solder and the like, and damage to the memory chip 11 and the like can be avoided during mounting the passive components 8.

Additionally, the passive component 8 can be located near the external terminal 7. Accordingly, a noise included in a signal which is inputted from outside of the semiconductor device via the external terminal 7 can be effectively removed. Furthermore, the controller chip 12 is provided above the package substrate 1. Therefore, a layout for interconnects which have the same length as a length of each other can be easily designed. It is particularly effective for the SSD which is operated at high speed.

### Fourth Embodiment

A semiconductor device according to a fourth embodiment will be explained. In the semiconductor device according to the fourth embodiment, a memory chip is provided on a package substrate, and a controller chip and passive components are provided in the package substrate. The description similar to that of the first to third embodiments will not be repeated.

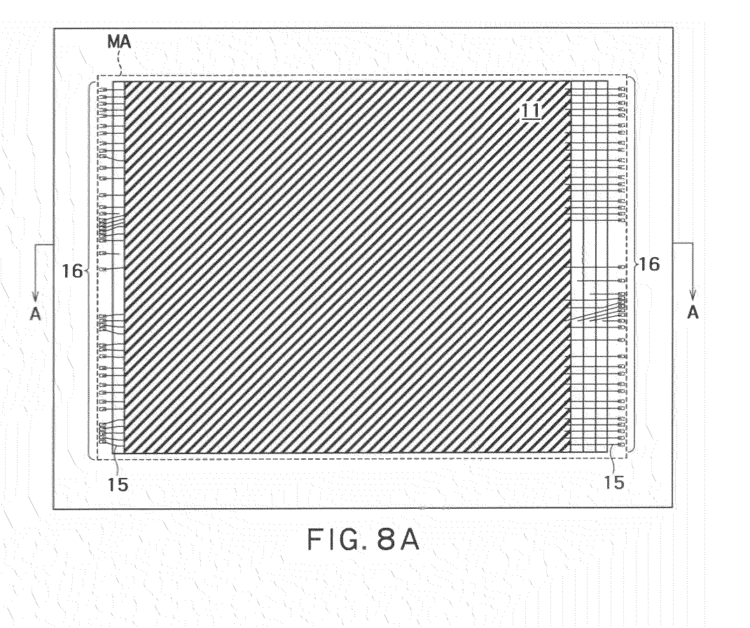

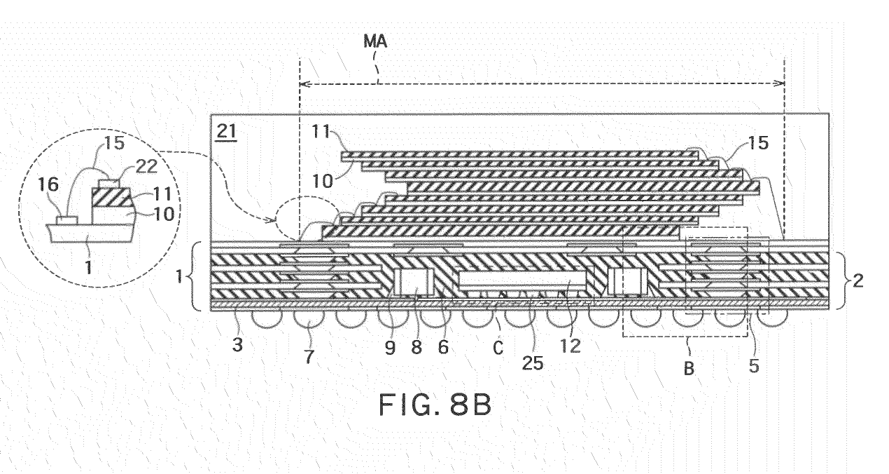

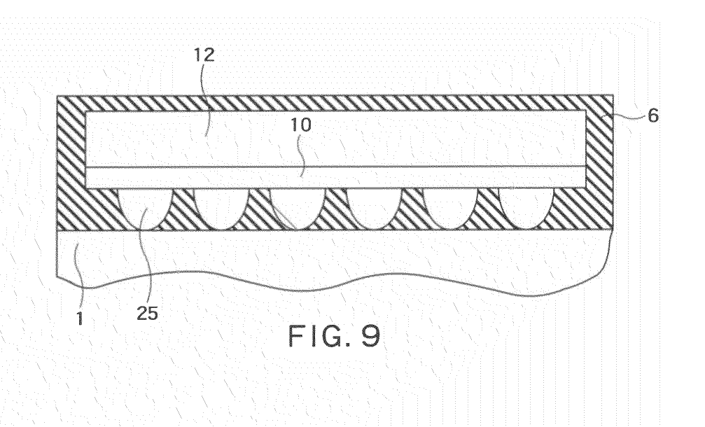

A configuration of the semiconductor device according to the fourth embodiment will be explained below. FIG. 8A is a plan view of the semiconductor device according to the fourth embodiment. FIG. 8B is a sectional view taken on a line A-A of FIG. 8A. FIG. 9 is an enlarged view of an area C of FIG. 8B.

As illustrated in FIG. 8B, the package substrate 1 includes the glass epoxy board 3, the electrode material 5, and the passive components 8. For example, the glass epoxy board 3 includes the glass board and the glass epoxy material in which an epoxy resin is cured on the glass board or the sheet-like pre-preg in which the epoxy resin is semi-cured. The electrode material 5 is similar to that of the first embodiment (see FIG. 2).

As illustrated in FIGS. 8A and 8B, the plural bonding pads 16 are provided on the package substrate 1. The bonding pads 16 are electrically connected to the uppermost layer (third interconnection layer) 2c of the plural interconnection layers 2 of FIG. 2.

As illustrated in FIG. 8B, the controller chip 12 is formed in the package substrate 1 with the bonding member 10 interposed therebetween. The memory chip 11 includes the plural first pads (memory pads) 22 on the upper surface thereof. In the fourth embodiment, the plural pairs of the bonding members 10 and the memory chips 11 are provided. The pairs of the bonding members 10 and the memory chips 11 are alternately stacked such that the center lines of the pairs are not overlapped. That is, the pairs of the bonding members 10 and the memory chips 11 are stacked such that the upper surface of the first pad 22 on the memory chip 11 of the lower layer is not overlapped on the pair of the bonding member 10 and the memory chip 11 of the upper layer.

As illustrated in FIG. 9, the bonding member 10 is provided on the lower surface of the controller chip 12 in the package substrate 1. Plural electrodes 25 are provided on the lower surface of the bonding member 10. Each electrode 25 is in contact with the second interconnection layer 2b. The controller chip 12 is connected to the second interconnection layer 2b with the electrode 25 interposed therebetween. The controller chip 12, the bonding member 10, and the plural electrodes 25 are covered with the insulating film layer 6. As illustrated in FIG. 8A, when the controller chip 12 and the memory chip 11 are viewed from above, the area of the controller chip 12 is smaller than that of the memory chip 11.

As illustrated in FIG. 8B, each first pad 22 on the memory chip 11 is connected to the bonding pad 16 on the package substrate 1 by the first wire 15. For example, the first wire 15 is made of a gold wire, a silver wire, a copper wire, or a mixture thereof.

In the fourth embodiment, the electrode material 5 is formed by the plural interconnection layers 2 and the plural bumps 4. However, the scope of the present invention is not limited to the fourth embodiment. Alternatively, for example, the through-hole is formed in the package substrate 1, and the conductive material may be buried in the through-hole to form the electrode material 5.

According to the fourth embodiment, the memory chip 11 is provided above the package substrate 1, and the controller chip 12 and the passive components 8 are provided in the package substrate 1. The controller chip 12 is connected to the package substrate 1 by flip chip connection. Therefore, the wire can be eliminated between the second interconnection layer 2b of the package substrate 1 and the controller chip 12, and the semiconductor device can be shrunk. Accordingly, the semiconductor device can be operated at high speed. Additionally, because the relay member 14 is not required, the production cost of the semiconductor device can be reduced. Additionally, because the controller chip 12 is provided in the package substrate 1, the height of the whole semiconductor device can be reduced.

At this point, when the semiconductor device is viewed from above, the memory chip 11 has the largest area among the areas of the memory chip 11, controller chip 12, and passive components 8. That is, when the semiconductor device is viewed from above, the controller chip 12, the passive components 8, and the relay member 14 are disposed so as to be included in the memory chip 11. As a result, the semiconductor device can be shrunk when the semiconductor device is viewed from above.

According to the fourth embodiment, the passive components 8 are provided in the package substrate 1. Accordingly, the passive components 8 can easily be mounted using the solder and the like, and the damage to the memory chip 11 and the like can be avoided during mounting the passive components 8.

Additionally, the passive component 8 can be located near the controller chip 12 and the external terminal 7. Accordingly, noises included in a signal which is inputted from outside of the semiconductor device via the external terminal 7 and in signals which are inputted to and outputted from the controller chip 12 can be effectively removed. Furthermore, the controller chip 12 and the passive components 8 are provided above the glass epoxy board 3 of the package substrate 1. Therefore, the layout for interconnects which have the same length as a length of each other can be easily designed. It is particularly effective for the SSD which is operated at high speed.

### Fifth Embodiment

A semiconductor device according to a fifth embodiment will be explained. In the semiconductor device according to the fifth embodiment, a memory chip is provided on a package substrate, a controller chip is provided in the package substrate, and passive components are provided in the package substrate such that part of the passive component is included in the memory chip. The description similar to that of the first to fourth embodiments will not be repeated.

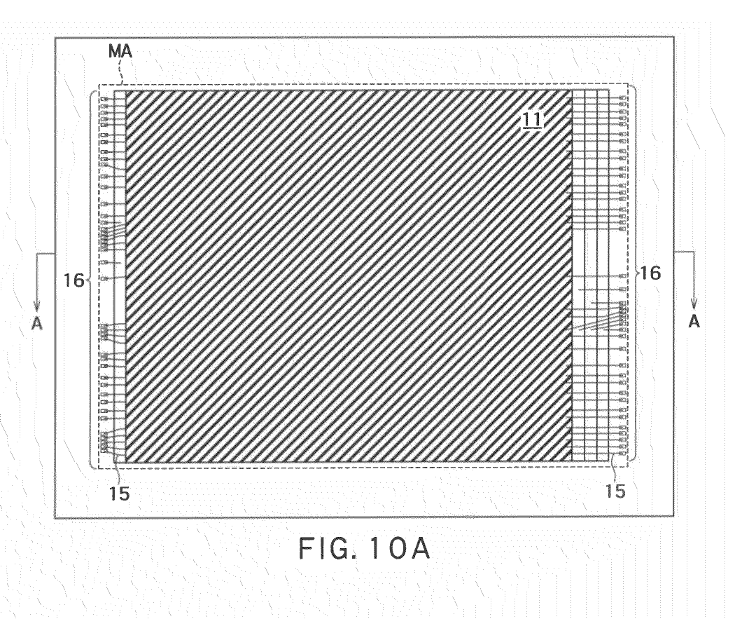

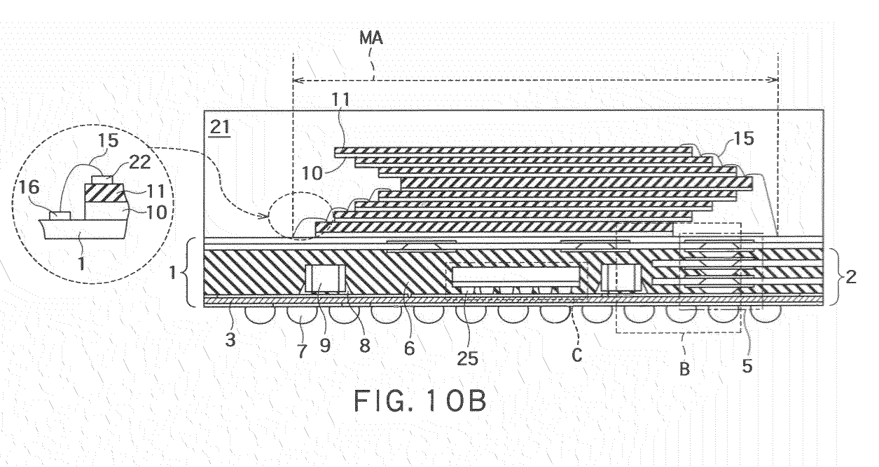

A configuration of the semiconductor device according to the fifth embodiment will be explained below. FIG. 10A is a plan view of the semiconductor device according to the fifth embodiment. FIG. 10B is a sectional view taken on a line A-A of FIG. 10A.

As illustrated in FIG. 10B, the package substrate 1 includes the glass epoxy board 3, the electrode material 5, and the passive components 8. For example, the glass epoxy board 3 includes the glass board and the glass epoxy material in which an epoxy resin is cured on glass board or the sheet-like pre-preg in which the epoxy resin is semi-cured. The electrode material 5 is similar to that of the first embodiment (see FIG. 2).

As illustrated in FIGS. 10A and 10B, the plural bonding pads 16 are provided on the package substrate 1. The bonding pads 16 are connected to the uppermost layer (third interconnection layer) 2c of the plural interconnection layers 2 of FIG. 2.

As illustrated in FIG. 10B, the controller chip 12 is formed in the package substrate 1 with the bonding member 10 interposed therebetween. The memory chip 11 includes the plural first pads (memory pads) 22 on the upper surface thereof. In the fifth embodiment, the plural pairs of the bonding members 10 and the memory chips 11 are provided. The pairs of the bonding members 10 and the memory chips 11 are alternately stacked such that the center lines of the pairs are not overlapped. That is, the pairs of the bonding members 10 and the memory chips 11 are stacked such that the upper surface of the first pad 22 on the memory chip 11 of the lower layer is not overlapped on the pair of the bonding member 10 and the memory chip 11 of the upper layer. In the fifth embodiment, the passive components 8 are provided such that part of the passive component 8 is located outside the memory chip 11.

Similarly to the fourth embodiment (see FIG. 9), the bonding member 10 is provided on the lower surface of the controller chip 12 in the package substrate 1. The plural electrodes 25 are provided on the lower surface of the bonding member 10. Each electrode 25 is in contact with the second interconnection layer 2b. The controller chip 12 is connected to the second interconnection layer 2b with the electrodes 25 interposed therebetween. The controller chip 12, the bonding member 10, and the plural electrode 25 are covered with the insulating film layer 6. As illustrated in FIG. 10A, when the controller chip 12 and the memory chip 11 are viewed from above, the area of the controller chip 12 is smaller than that of the memory chip 11.

As illustrated in FIG. 10B, each first pad 22 on the memory chip 11 is connected to the bonding pad 16 on the package substrate 1 by the first wire 15. For example, the first wire 15 is made of a gold wire, a silver wire, a copper wire, or a mixture thereof.

According to the fifth embodiment, as illustrated in FIGS. 10A and 10B, when the semiconductor device is viewed from above, the semiconductor device can be shrunk when the passive components 8 are disposed in the bonding pad 16 (that is, in the memory area MA) connected to the wire 15 without the passive components 8 in the memory chip 11. At this point, when the semiconductor device is viewed from above, the size of the semiconductor device depends on that of the package substrate 1. When the semiconductor device is viewed from above, the size of the package substrate 1 depends on not the size of the memory chip 11 but the position of the bonding pad 16. That is, as illustrated in FIGS. 10A and 10B, when the semiconductor device is viewed from above, the semiconductor device can be shrunk when the passive components 8 are included in the bonding pad 16 (that is, in the memory area MA), although the passive components 8 are not included in the memory chip 11. In other words, when the semiconductor device is viewed from above, the semiconductor device can be shrunk because the controller chip 12, the passive components 8, and the relay member 14 are included in the memory area MA.

In the fifth embodiment, the electrode material 5 is formed by the plural interconnection layers 2 and the plural bumps 4. However, the scope of the present invention is not limited to the fifth embodiment. Alternatively, for example, the through-hole is formed in the package substrate 1, and the conductive material may be buried in the through-hole to form the electrode material 5.

In the embodiments, various memory chips, such as a DRAM (Dynamic Random Access Memory) chip and an SRAM (Static Random Access Memory) chip, which are used as a cache memory, may be stacked on the memory chip 11.

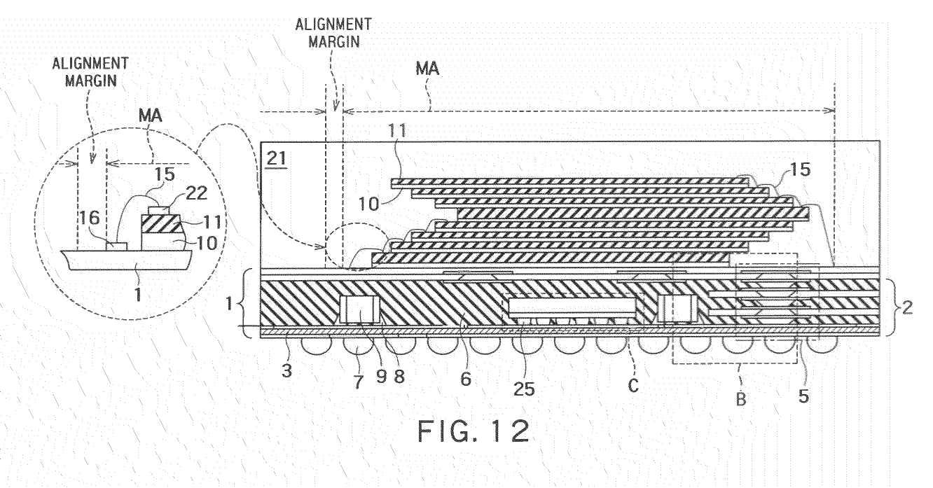

In the embodiments, an end portion of the package substrate 1 may not be flush with an end portion of the bonding pad 16. That is, the end portion of the package substrate 1 and the end portion of the bonding pad 16 may be separated from each other by a predetermined distance. A gap between the package substrate 1 and the bonding pad 16 is an alignment margin when the bonding pad 16 is formed in the package substrate 1. When the semiconductor device is viewed from above, a size of the semiconductor device depends on the alignment margin of the bonding pad 16 in addition to the position of the bonding pad 16 on the package substrate 1. Therefore, the memory area MA may be extended not up to the position of the bonding pad 16, but up to the position including the alignment margin of the bonding pad 16, as shown in FIG. 12

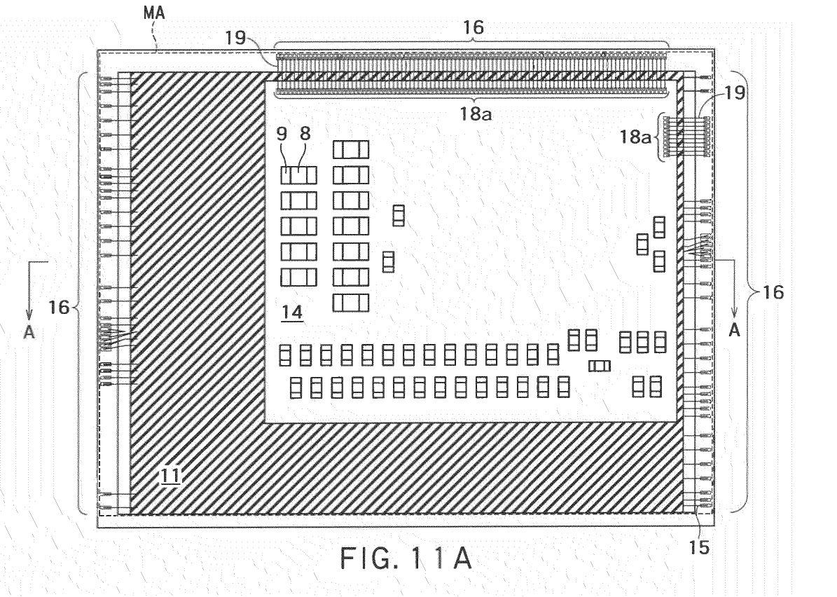

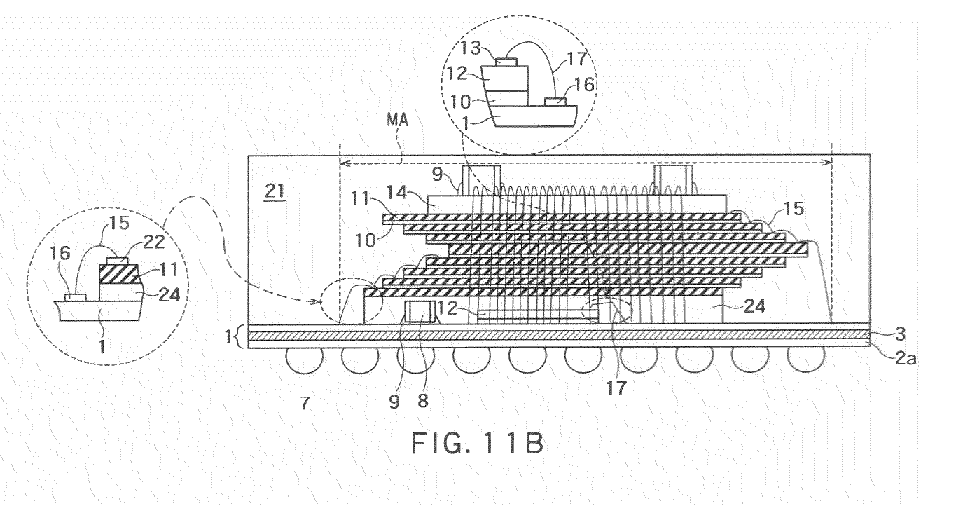

Additionally, in the embodiments, as shown in FIGS. 11A and 11B, the second embodiment may be combined with the third embodiment. In a semiconductor device according to an alternative embodiment in which the second embodiment is combined with the third embodiment, the memory chip 11 is provided above the package substrate 1, the controller chip 12 and the passive components 8 are provided between the package substrate 1 and the memory chip 11, and the relay member (relay substrate) 14 is provided above the memory chip 11. Also, the passive components 8 are provided above the relay member (relay substrate) 14. The controller chip 12 is connected to the package substrate 1 by the wire bonding connection. The passive components 8 are connected to the second interconnection layer 2b and the relay member (relay substrate) 14 by the conductive material 9. Therefore, the controller chip 12 is electrically connected to the passive components 8. When there is a space in which all the passive components 8 can be included between the package substrate 1 and the memory chip 11, the relay member (relay substrate) 14 and the passive components 8 above the relay member (relay substrate) 14 can be eliminated. That is, because the passive components 8 which can not be provided between the package substrate 1 and the memory chip 11 are provided above the memory chip 11, the semiconductor device can be shrunk when the semiconductor device is viewed from above.

Additionally, in the embodiments, the passive components 8 can be located near the controller chip 12 and the external terminal 7. Accordingly, the noises included in the signal which is inputted from outside of the semiconductor device via the external terminal 7 and in the signals which are inputted to and outputted from the controller chip 12 can be effectively removed. Furthermore, the layout for interconnects which have the same length as a length of each other can be easily designed because the controller chip 12 and the passive components 8 are above the package substrate 1. It is particularly effective for the SSD which is operated at high speed.

The embodiments can be applied to not only the SSD but also other semiconductor devices in which the passive component 8 needs to be disposed for the purpose of high-speed operation.

According to the embodiments, the passive component 8, the memory chip 11, and the controller chip 12 are provided in one package, which allows the semiconductor device to be shurnk. As a result, the semiconductor device that is mounted on compact instruments such as a mobile telephone can be provided.

According to the embodiments, the plural memory chips 11 may continuously be stacked. Accordingly, not only the above-described effect is obtained, but also the large-capacity semiconductor device can be obtained.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a base comprising a bonding pad;
a memory chip provided above the base and connected to the bonding pad by a wire, data being capable of being electrically stored in the memory chip;
a controller chip provided in a memory area comprising the memory chip in a direction from the memory chip toward the base and configured to control an operation of the memory chip; and
a plurality of passive components provided in the memory area.

2. The device of claim 1, wherein
an area of the controller chip is smaller than an area of the memory chip, and
the controller chip and all the plurality of passive components are provided in the memory area.

3. The device of claim 2, wherein the controller chip is provided between the base and the memory chip.

4. The device of claim 2, further comprising a relay member configured to relay a wire connecting the controller chip with the base, wherein
the plurality of passive components are provided on the relay member.

5. The device of claim 3, further comprising a relay member configured to relay a wire connecting the controller chip with the base, wherein
the plurality of passive components are provided on the relay member.

6. The device of claim 2, further comprising a relay member configured to relay a wire connecting the controller chip with the base, wherein
the controller chip is provided above the memory chip, and
the plurality of passive components are provided on the relay member.

7. The device of claim 2, wherein the controller chip is provided in the base.

8. The device of claim 2, wherein all the plurality of passive components are provided in the base.

9. The device of claim 7, wherein all the plurality of passive components are provided in the base.

10. A semiconductor device comprising:
a base comprising bonding pads;
a memory chip provided above the base and connected to the bonding pad by a wire, data being capable of being electrically stored in the memory chip;
a controller chip provided in a memory area comprising the memory chip in a first direction from the memory chip toward the base and configured to control an operation of the memory chip; and
a plurality of passive components provided in the memory area, wherein
the memory area is sandwiched in between bonding pads located at both ends of the plural bonding pads on the base and includes the memory chip in view of the first direction.

11. The device of claim 10, wherein the plurality of passive components are provided in the base.

12. The device of claim 10, wherein the memory area comprises an alignment margin of the bonding pads.
